(19) United States
(12) Patent Application Publication
(10) Pub. No.: US 2010/0247804 A1
(43) Pub. Date: Sep. 30, 2010

(54) BIASABLE COOLING PEDESTAL

(75) Inventor: Shambhu Roy, Sunnyvale, CA (US)

Correspondence Address: FISH & RICHARDSON P.C., P.O. BOX 1022, MINNEAPOLIS, MN, 55440-1022, US

(73) Assignee: Applied Materials, Inc., Santa Clara, CA (US)

(21) Appl. No.: 12/730,762

(22) Filed: Mar. 24, 2010

Related U.S. Application Data
(60) Provisional application No. 61/162,985, filed on Mar. 24, 2009.

(51) Int. Cl. C23C 16/44; C23C 16/00

(52) U.S. Cl. 427/569; 118/723 R

(57) ABSTRACT

In some embodiments, a method for cooling a substrate upon a biasable cooling pedestal for supporting a substrate during deposition within a plasma vapor deposition chamber may include a supplying a low pressure inert gas from the shaft of a liquid-chilled pedestal to flow through one or more channels within grooved a metal substrate support and a liquid-chilled body. By maintaining a cooling gas supply at a pressure well below that which may displace the weight of the substrate, the gas may enable even heat transfer between the cooling pedestal and the substrate to cool the substrate during deposition without the use of electrical or mechanical mechanisms for clamping the substrate in place.

### CROSS-REFERENCE TO RELATED APPLICATIONS

This application claims the benefit of U.S. Provisional Application Ser. No. 61/162,985, filed on Mar. 24, 2009, and entitled “BIASABLE COOLING PEDESTAL,” the contents of which are hereby incorporated by reference.

### BACKGROUND

In the fabrication of integrated circuits and displays, semiconductor, dielectric, and electrically conducting materials are formed on a substrate, such as a silicon substrate or a glass substrate. The materials can be formed by chemical vapor deposition (CVD), atomic layer deposition (ALD), physical vapor deposition (PVD), ion implantation, plasma or thermal oxidation, and/or nitridation processes, to name a few examples. Thereafter, the deposited materials can be etched to form features such as gates, vias, contact holes and interconnect lines. In some depositions or etch processes, the substrate is exposed to a plasma in a substrate processing chamber to deposit or etch material on the substrate surface. Other processes that may be performed on a substrate include thermal processing techniques such as rapid thermal processing (RTP), flash lamp, or laser annealing processes.

PVD, or sputtering, is one of the processes used in fabrication of integrated circuits and devices. PVD is a plasma process performed in a vacuum chamber where a negatively biased target (typically, a magnetron target) is exposed to a plasma of an inert gas having relatively heavy atoms (e.g., argon (Air)) or a gas mixture comprising such inert gas. Bombardment of the target by ions of the inert gas results in ejection of atoms of the target material. The ejected atoms accumulate as a deposited film on a substrate placed on a substrate pedestal which generally faces the target. During the processes discussed above, the substrate (also referred to as a wafer) can be held on a substrate support (also known as a wafer pedestal or susceptor) having a substrate receiving surface. In some implementations, a radio frequency (RF) electric field can be applied between an RF electrode portion of the substrate support and the chamber to generate a plasma within the chamber and/or bias the plasma towards the substrate.

During some processes, such as high power PVD, the wafer may become extremely hot and could be damaged if the wafer is not cooled. For example, a wafer may be cooled by applying a cooling gas between the wafer and the pedestal. This is a cooling technique known in art as “backside cooling”. Without a backside cooling gas, the interstices between the substrate support and the substrate can become filled with the chamber atmosphere, e.g., a vacuum or partial vacuum. As such, heat conduction from the substrate to the support may be limited to points of physical contact between the substrate and the substrate support. Since, on a microscopic level, the substrate may not be perfectly flat, the points of contact between the substrate and the substrate support may be few and, as such, may not provide substantial heat conduction.

### SUMMARY

In one embodiment, a method for cooling a substrate upon a biasable cooling pedestal during deposition within a plasma vapor deposition chamber may include supplying a low pressure inert gas from the shaft of a liquid-chilled pedestal to flow through one or more channels within a metal substrate support. By maintaining a cooling gas supply at a pressure below that which may displace the weight of the substrate, the gas may enable even heat transfer between the cooling pedestal and the substrate to cool the substrate during deposition without the use of electrical or mechanical mechanisms for clamping the substrate in place. In an illustrative embodiment, a metal cooling pedestal may include a number of channels (e.g., radially and/or circumferentially arranged upon the surface of the substrate support, or otherwise interconnected in a labyrinth pattern), the channels facing the substrate. To avoid pressure build up, a flow rate controller may limit the gas flow provided to the gas channel(s) on the surface of the substrate support, and gas may be dispersed into the processing chamber through channel areas extending beyond the circumference of the substrate.

In another illustrative embodiment, the pedestal may additionally include a series of pins or a ring such that the substrate is nested within the circumference of the pins or ring. The pins or ring, for example, may prevent the substrate from shifting horizontally due to pressure built up from the inert gas supply. The cooling pedestal, in some embodiments, may include a radio frequency (RF) electron portion to bias the plasma toward the substrate during deposition.

### DESCRIPTION OF DRAWINGS

FIG. 1 depicts a cross-sectional schematic view of a physical vapor deposition (PVD) chamber.

FIG. 2 depicts a top view of an exemplary substrate support platform for use in backside gas cooling of a substrate.

FIG. 3 depicts a side view of an exemplary substrate support for use in backside gas cooling of a substrate.

FIG. 4 depicts a cross-sectional schematic view of the exemplary substrate support of FIG. 3.

FIG. 5 depicts an exemplary substrate support platform for use in backside gas cooling of a substrate with alignment pins for maintaining the horizontal position of the substrate.

### DETAILED DESCRIPTION OF ILLUSTRATIVE EMBODIMENTS

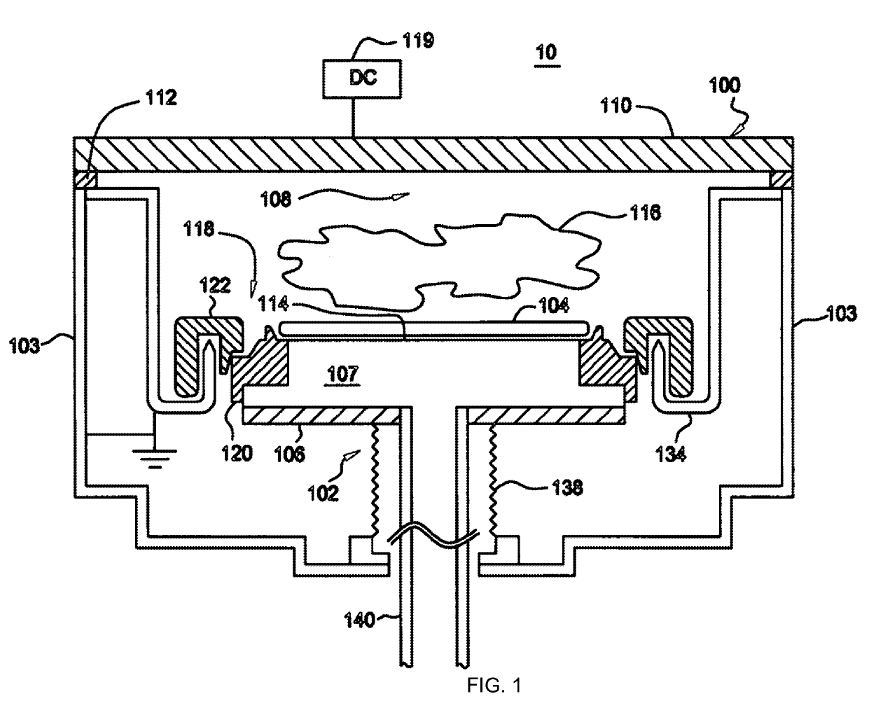

FIG. 1 depicts a schematic cross-sectional view of a physical vapor deposition (PVD) process chamber 10. The PVD process chamber 10 generally includes a vacuum chamber 100. The vacuum chamber 100 comprises a set of walls 103 that define a volume. A pedestal assembly 102 is positioned within the volume defined by walls 103. The PVD process chamber 10 may be maintained at a pressure within a range of about 1 milliTorr to about 20 Torr, for example.

The pedestal assembly 102 comprises a pedestal 106 and a susceptor 107. The susceptor 107 has a surface 114 that can support a wafer 104 or any other substrate. The pedestal 106 is connected to a lift mechanism 138 or other actuator disposed through the bottom portion of the chamber 100. In some implementations, the pedestal assembly may be maintained at a temperature less than about 200° C. In use, the susceptor 107 is moved upwards into deposition position by the lift mechanism 138 and a plasma 116 is formed in a reaction zone 108 above the wafer 104.

A chamber lid 110 at the top of the chamber 100 contains deposition target material. The target material may comprise metals including for example, titanium, tungsten, copper, aluminum and tantalum, among others, as well as alloys such as, for example, nickel-vanadium, among others. Alternatively, a separate target (not shown) may be suspended from the chamber lid 110. The target provides a sputtering surface positioned to deposit sputtered material onto a top surface of the wafer 104. The chamber lid 110 is negatively biased by a sputter power source 119 to form a cathode.

The chamber lid 110 is electrically insulated from the remainder of the chamber 100. Specifically, an insulator ring 112 electrically isolates the chamber lid 110 from a grounded annular shield member 134 so that a negative voltage may be maintained on the target.

Sputter deposition processes can be performed using a process gas such as an inert gas (e.g., argon (Ar), helium (He), xenon (Xe) and neon (Ne)) that is provided to the chamber 100 at a selected flow rate regulated by a mass flow controller. For nitride formation (e.g., titanium nitride (TiN), nickel vanadium nitride (NiVN)) a nitrogen-containing gas (e.g., nitrogen (N₂)) is provided to the chamber 100 to react with the sputtered target material.

The sputter power source 119 applies a negative voltage to the target in the chamber lid 110 with respect to the grounded annular shield member 134 to excite the inert gas provided to the chamber 100 into a plasma state. Ions from the plasma bombard the target surface and sputter target material from the target. The sputter power source 119 used for target biasing purposes may be any type of power supply including DC, pulsed DC, AC, RF and combinations thereof. Sputter powers of up to about 50 kilowatts may be used.

The vacuum chamber 100 here includes a ring assembly 118 that prevents deposition from occurring in unwanted locations such as, upon the sides of the susceptor 107, beneath the pedestal. Specifically, a waste ring 120 and cover ring 122 can prevent sputtered material from being deposited on selected surfaces other than the wafer 104.

Additionally, substrate bias circuitry may be included (e.g., within a pedestal shaft 140 or elsewhere) to provide a bias to the wafer 104 to direct the ionized metal particles toward the wafer 104. The substrate bias circuitry may include a bias RF power supply that is coupled to the susceptor 107 through a matching network. As another example, a feedback controller can control the bias power along with a reflected bias power that is applied to the wafer 104. The controller can be a programmable microprocessor, or any other switching controls can be utilized, for example. The wafer bias power can range from, for example, about 3.2×10⁻³ watts/mm² to about 1.6×10⁻² watts/mm². A reflected bias power up to about 9.6×10⁻³ watts/mm² may be used, for example.

It is believed that the magnitude of the bias power controls the intrinsic stress of as-deposited films by changing the force with which the ionized metal particles bombard the surface of the wafer. In particular, as the magnitude of the power is increased the force with which the ionized metal particles bombard the surface of the wafer is reduced. Alternatively, the magnitude of the bias power in combination with the reflected bias power may be used to control the intrinsic stress of the as-deposited films by changing the force with which ionized metal particles bombard the surface of the wafer.

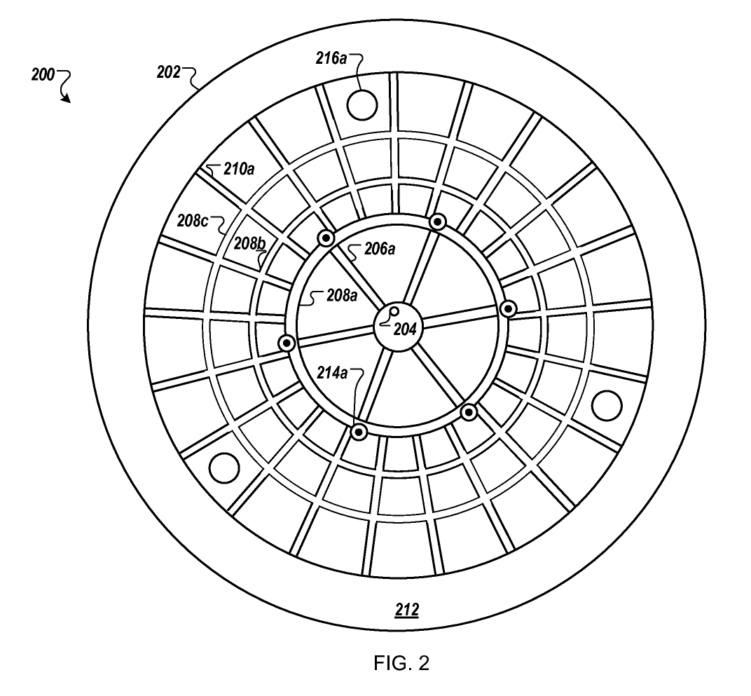

FIG. 2 depicts a top view 200 of an exemplary substrate support platform 202 that can be used in backside gas cooling of a substrate. For example, the susceptor 107 (as shown in FIG. 1) may be implemented similarly or identically to the substrate support platform 202. The support platform 202 includes a gas outlet 204 which introduces an inert gas (e.g., He, Ar, or N²) into an interconnected series of radial gas channels 206, 210 and concentric gas channels 208. For example, the channels 206, 208 and 210 can be formed as grooves or other depressions in the surface of the platform 202 using any suitable technique.

The radial gas channels 210 can extend to an outer edge 212. The outer edge 212, in some implementations, may partially or fully seal ends of the radial gas channels 210. In other implementations, the outer edge 212 may be formed upon a plane at or below the depth of the gas channels 206, 208, and 210 such that the ends of the channels 210 are not sealed and gas flowing along the radial gas channels 210 disperses into the chamber atmosphere upon exiting the radial gas channels 210 at the outer edge 212. For example, the ends of the radial gas channels 210 may be open to the atmosphere of the processing chamber to avoid gas pressure build-up beneath the substrate. In another example, the substrate may be smaller in diameter than outer termination points of the radial gas channels 210. During a processing action, the radial gas channels 206, 210 and the concentric gas channels 208 transport inert gas beneath a substrate to improve heat transfer between the substrate and the substrate support platform 202.

The substrate support platform 202 may further include one or more mounting bolts such as a first mounting bolt 214a or a series of lift pin entry points 216 for aid in substrate placement within and removal from a processing chamber. In some implementations, the lift pin entry points 216 may be designed and positioned to additionally provide a portal through which cooling gas can escape from the gas channels 208 or 210.

The substrate support platform 202, in some implementations, may be manufactured from aluminum, steel, titanium, beryllium copper, or another metal or metal composite. The gas channels 206, 208, and 210 may be formed within the face of the substrate support platform 202, for example, by etching, machining, or electrical discharge machining (EDM). Although the gas channels 206, 208, 210 are illustrated arranged in an even distribution of radial spokes and concentric circles, other gas channel configurations are possible. In some implementations, individual gas channels 206, 208, or 210 or sets of gas channels 206, 208, or 210 may differ from each other by width or depth. For example, the radial gas channels 206 or 210 may taper in width to maintain an even gas pressure while flowing away from the center of the substrate support platform 202. In other implementations, rather than gas channels, a series of gas outlets (e.g., arranged concentrically like a showerhead) may be included to provide even gas supply to the back side of a substrate.

The gas channels 206, 208, and 210 may be designed to encourage heat transfer while allowing the substrate to remain substantially within a single position without the aid of a mechanical or electrical mechanism for clamping the substrate in place. In one example, a physical clamp may block too great a portion of a substrate from processing. Further, the substrate being processed may be formed of a non-conductive material, such as glass or silicon bonded to glass, which may not be capable of being electrically chucked to the surface of a substrate support. In another example, the substrate may be bowed or warped such that an electric clamping mechanism would not be as effective. In these circumstances, to reduce thermal stress upon the substrate, the substrate support platform 202 may be used to apply backside gas cooling to a substrate through providing a low pressure supply of gas to the gas channels 206, 208, and 210 through the gas outlet 204.

If a silicon substrate is placed on the substrate support platform 202, for example, it may require more than 200 milliTorr pressure to displace the weight of the substrate. In some implementations, the flow rate of the gas introduced to the gas outlet 204 can be controlled to maintain a pressure differential between the top of the substrate and the bottom of the substrate of less than 125 milliTorr. In one example, a ten standard cubic centimeters per minute (SCCM) supply of argon gas may be provided through the gas outlet 204 by a flow rate controller (e.g., connected to a gas inlet of a gas conduit feeding the gas outlet 204) to generate a pressure differential between the top side of the substrate and the bottom side of the substrate of approximately thirty milliTorr.

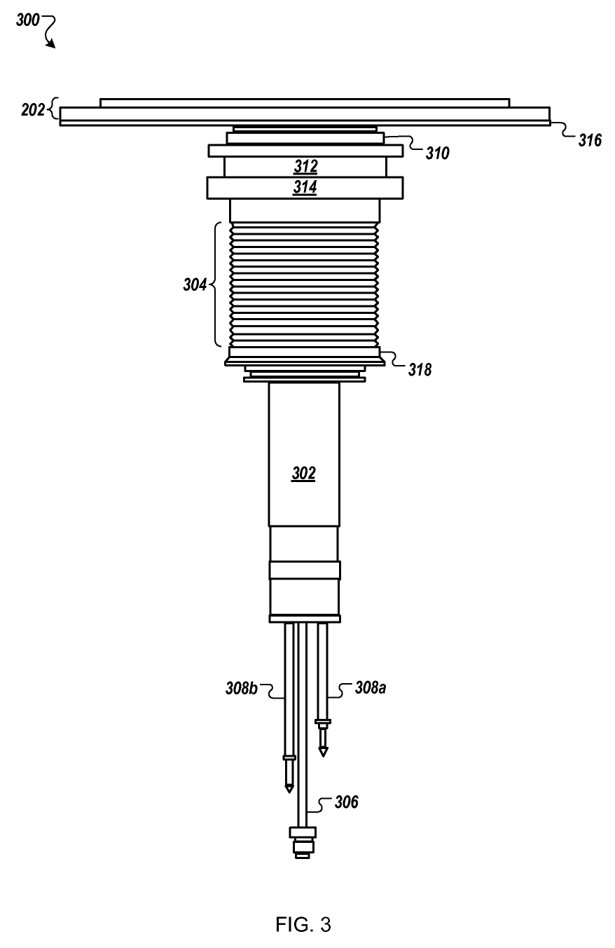

FIG. 3 depicts an exemplary substrate support 300 for use in backside gas cooling of a substrate. The substrate support 300 can include the substrate support platform 202 positioned upon a support shaft 302. The support shaft 302, in some implementations, may include a bellows 304 for protecting moving parts from chamber contaminants within a lifting substrate support apparatus. Gas can be provided to the substrate support platform 202 through the support shaft 302 via a gas conduit 306. Liquid and gas are introduced to the substrate support platform 202 from the support shaft 302 through a liquid/gas integration flange 310 (e.g., including a gas inlet and a liquid inlet).

To maintain a consistent temperature during processing or through repeated processing actions, the substrate support 300 may be liquid cooled. A liquid inlet conduit 308a and a liquid outlet conduit 308b may facilitate the circulation of a cooled liquid (e.g., water, propylene glycol, a water-glycol mixture, or other low temperature liquid) through the substrate support 300. In some implementations, the temperature of the substrate support platform 202 may be maintained at approximately 200° C. or below by circulating liquid through liquid cooling channels within the support platform 202. In one example, water may be circulated through the substrate support 300 at a flow rate of approximately 0.6 gallons per minute to maintain a substrate support temperature within a range of 150° C. to 190° C.

In some implementations, the substrate support 300 may direct radio frequency (RF) energy through the substrate support platform 202 to bias the plasma towards the substrate during deposition processing. In this configuration, to prevent arcing within the processing chamber, the support platform 202 may be electrically isolated from the substrate support 300 using an electric isolator ring 312 between the liquid/gas integration flange 310 and a bellows flange 314 or an electric isolator ring 316 directly beneath the support platform 202. Additionally, the substrate support platform 202 may be electrically grounded at a lower bellows flange 318. In some implementations, RF energy at a frequency of 13.56 MHz can be directed through the substrate support platform 202. Thus, while the substrate is not mechanically or electrically held to the platform by any mechanical or electrostatic device, gas can cool the substrate from below without substantially moving the substrate and the RF energy can bias the plasma towards the substrate.

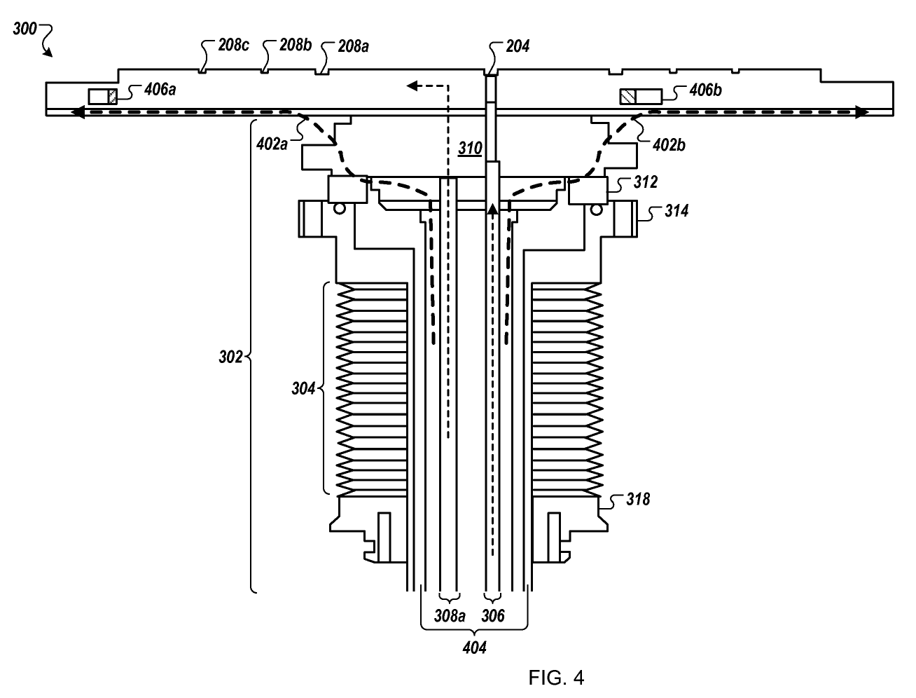

FIG. 4 depicts a cross-sectional schematic view of the exemplary substrate support 300 of FIG. 3. A pair of RF energy path arrows 402 illustrates the path that RF energy may take from the support shaft 302 to the substrate support platform 202. The gas conduit 306 and liquid conduit(s) 308 may be included within an RF application tube and flange 404. RF energy applied to the RF application tube and flange 404, for example, may travel upwards towards the substrate support platform 202 to the electric isolator ring 312 which routes the energy through the outer edge of the liquid/gas integration flange 310. The electric isolator ring 316 provides a conductivity path for the RF energy to enter the region of the support platform 202. The bellows 304, bellows flange 314, and lower bellows flange 318, in some implementations, are grounded to prevent arcing within the processing chamber while the substrate support platform 202 is RF biased. In other implementations, rather than including the configuration of the RF application tube and flange 404, an RF application rod (not illustrated) may be mounted to the liquid/gas integration flange 310.

The substrate support platform 202 also receives cooling gas from the gas conduit 306 through the gas outlet 204. The cooling gas is distributed, for example, through the concentric gas channels 208 and the radial gas channels 206, 210 (not illustrated). The cooling gas encourages heat transfer between the substrate (not illustrated) and the substrate support platform 202.

The substrate support platform 202 may be maintained at a desired general temperature using cooling liquid supplied to the substrate support platform 202 through the liquid inlet conduit 308a. The cooling liquid is circulated through the substrate support platform 202 through one or more liquid channels 402. The liquid then exits the substrate support platform 202 and travels back down the support shaft 302 through the liquid outlet conduit 308b (not illustrated). The liquid channels 402, in some implementations, may be created through machining, drilling, or brazing, in some examples. The substrate support platform 202, for example, may be created from two metal halves which are brazed or welded, or bolted together (e.g., with an o-ring between) after the liquid channels 402 have been created.

The processing chamber, in some implementations, may include a refrigerant element which lowers the temperature of the returned liquid to a predetermined chilled temperature before recycling the liquid through the liquid inlet conduit 308a. For example, a refrigerant element may be employed to maintain a liquid coolant temperature around 20° C., −20° C., or −40° C. depending upon the liquid used.

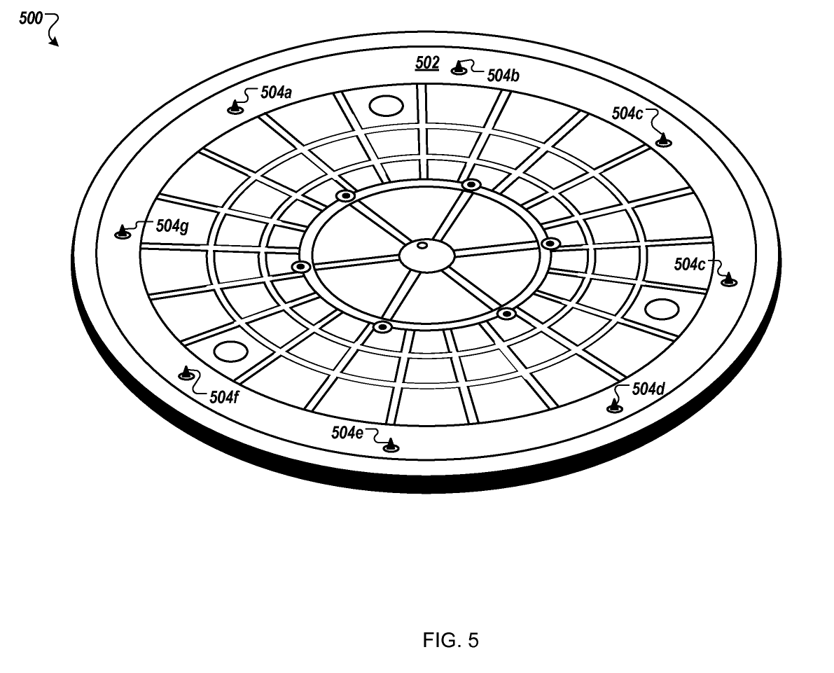

FIG. 5 depicts an exemplary substrate support platform 500 for use in backside gas cooling of a substrate with a set of alignment pins 504 arranged along the edges of a deposition ring 502 for maintaining the horizontal position of the substrate during application of backside gas cooling. The substrate support platform 500 includes an interconnected series of radial and concentric gas channels (as described in relation to FIG. 2) to distribute backside cooling gas evenly along the bottom of the substrate.

Gas channels may be arranged in an even and/or symmetrical pattern. The bottom surface of a substrate, however, may not be perfectly flat or otherwise symmetric. Depending upon the material used, for example, interstices, or pores, within the substrate material can develop unevenly upon the surface. In another example, some processing techniques can cause bowing or curving of the substrate surface. The cooling gas can penetrate the microscopic pores and uneven surfaces, causing uneven regions of gas pressure force. If the gas pressure force is great enough upon the substrate, the pressure may horizontally displace the substrate across the surface of the substrate support platform 500. This may in turn affect the evenness of the processing taking place within the processing chamber.

The set of alignment pins 504, arranged within the deposition ring 502 approximately along the diameter of a substrate which may be introduced for processing, may be used to block the horizontal displacement of the substrate. Here illustrated as a series of vertical pins, in other implementations the alignment pins 504 may be implemented otherwise, such as in form of curved pins or a contiguous raised ring (upright or slanted) of a height at least great enough to arrest the horizontal movement of the substrate. The deposition ring 502, in some implementations, may be positioned within a lower plane relative to the substrate support surface including the gas channels. For example, the deposition ring 502 may be positioned at the same vertical depth as the bottom of the gas channels. The alignment pins 504, in this example, may be greater in height than the depth of the gas channels such that the tips of the alignment pins 504 extend above the planar level of the top of the gas channels.

A number of embodiments have been described. It is contemplated that a plurality of the aforementioned specific features can be combined into a single device, as will be understood by those skilled in the art. Nevertheless, it will be understood that various modifications may be made without departing from the spirit and scope of this disclosure. Accordingly, other embodiments are within the scope of the following claims.

What is claimed is:

1. A method comprising:
heating a substrate within a substrate processing chamber, the substrate being supported by a support surface of a pedestal in the processing chamber wherein the substrate is free-standing on the pedestal and not held in place electrically or mechanically;
reducing an ambient pressure within the substrate processing chamber;
generating a plasma within the processing chamber;
cooling the substrate by supplying a gas between a bottom side of the substrate and the support surface, the supplied gas producing a pressure differential between the bottom side of the substrate and a top side of the substrate, the pressure differential being sufficiently low to permit the substrate to remain substantially stationary during the cooling of the substrate; and
cooling at least a portion of the pedestal by supplying a fluid to an internal conduit inside the pedestal.

2. The method of claim 1, wherein the pressure differential between the bottom side of the substrate and the top side of the substrate is 150 milliTorr or less.

3. The method of claim 2, wherein the pressure differential between the bottom side of the substrate and the top side of the substrate is within a range between about 20 milliTorr and about 50 milliTorr.

4. The method of claim 1, further comprising maintaining the substrate at a substrate temperature of 200° C. or less.

5. The method of claim 4, wherein the substrate temperature is maintained within a range of about 100° C. to about 150° C.

6. The method of claim 4, further comprising maintaining the support surface of the pedestal at a support surface temperature below 200° C., wherein the support surface temperature is held at an approximately set temperature throughout repeated processing actions.

7. The method of claim 1, further comprising biasing the plasma towards the substrate by applying radio frequency energy to a portion of the pedestal.

8. The method of claim 7, further comprising electrically isolating a portion of the support surface from the pedestal to prevent arcing during the processing action.

9. The method of claim 1, further comprising preventing the substrate from being displaced substantially within a horizontal direction, the substrate being prevented from displacement by a raised portion of the support surface bordering the diameter of the substrate.

10. The method of claim 1, further comprising distributing the gas beneath the substrate through at least one channel formed within the support surface.

11. The method of claim 10, wherein the channel extends beyond a diameter of the substrate such that the gas disperses into the substrate processing chamber rather than allowing pressure to build up beneath the substrate.

12. A method comprising:
supporting a substrate upon a support surface of a pedestal in a substrate processing chamber, the substrate being free-standing on the pedestal and not held in place electrically or mechanically;
reducing an ambient pressure within the substrate processing chamber;
electrically isolating a portion of the support surface from the pedestal to prevent arcing;
heating the substrate within the substrate processing chamber;
generating a plasma within the processing chamber;
biasing the plasma towards the substrate by applying radio frequency energy to a portion of the pedestal;
cooling at least a portion of the pedestal by supplying a fluid to an internal conduit inside the pedestal;
maintaining the support surface of the pedestal at a support surface temperature below 200° C., wherein the support surface temperature is held at an approximately set temperature throughout repeated processing actions;
supplying a gas to an internal conduit inside the pedestal, the internal conduit opening to a gas inlet on the support surface of the pedestal;
cooling at least the substrate by supplying a gas between a bottom side of the substrate and the support surface;
controlling a gas pressure of the gas to maintain a pressure differential between the bottom side of the substrate and a top side of the substrate sufficiently low enough to permit the substrate to remain substantially stationary during the cooling of the substrate of less than that which could substantially displace the weight of the substrate upon the support surface; and
maintaining the substrate at a substrate temperature of 200° C. or below.

13. A system comprising:
a substrate processing chamber;
a power source coupled to the substrate processing chamber, the power source used to excite an inert gas provided to the substrate processing chamber into a plasma state for plasma processing; and
a substrate support pedestal mounted in the substrate processing chamber, wherein the substrate support pedestal comprises:
a support shaft;
a support surface on top of the support shaft, the support surface capable of supporting a substrate;
a gas supply conduit inside the support shaft, the gas supply conduit supplying cooling gas from a gas inlet in the support shaft to a gas outlet on a top side of the support surface, the gas outlet supplying gas to a bottom side of the substrate, the gas producing a pressure differential between the bottom side of the substrate and a top side of the substrate; and
a flow rate controller coupled to the gas inlet, the flow rate controller providing a flow rate selected to maintain the pressure differential in a range permitting the substrate to remain substantially stationary during cooling of the substrate.

14. The system of claim 13, wherein the substrate support pedestal further comprises a fluid supply conduit inside the support shaft and the support surface, the fluid supply conduit circulating cooling liquid in an interior channel of the support surface to cool the substrate.

15. The system of claim 14, further comprising:
a refrigerant element coupled to the fluid supply conduit, the refrigerant element capable of maintaining a temperature of the cooling liquid at or below twenty degrees Celsius.

16. The system of claim 13, wherein the gas outlet opens to a cooling gas channel in the top side of the support surface, the cooling gas channel extending beyond a diameter of the substrate such that the gas disperses into the substrate processing chamber rather than allowing pressure to build up beneath the substrate.

17. The system of claim 16, wherein the cooling gas channel includes at least one concentric gas channel and at least one radial gas channel, the radial gas channel being fluidly connected to the concentric gas channel, the concentric gas channel transporting gas beneath the substrate, and the radial gas channel extending beyond the diameter of the substrate.

18. The system of claim 13, wherein a top side of the support surface includes a raised portion of the support surface bordering a diameter of the substrate, the raised portion preventing the substrate from being displaced substantially within a horizontal direction.

19. The system of claim 13, wherein the substrate support pedestal further comprises an RF energy path between the support shaft and the support surface, the RF energy path allowing an RF bias on the substrate support during plasma processing.

20. A system comprising:
means for heating a substrate within a substrate processing chamber, the substrate being supported by a support surface of a pedestal in the processing chamber wherein the substrate is free-standing on the pedestal and not held in place electrically or mechanically;
means for reducing an ambient pressure within the substrate processing chamber;
means for generating a plasma within the processing chamber;
means for cooling the substrate by supplying a gas between a bottom side of the substrate and the support surface, the supplied gas producing a pressure differential between the bottom side of the substrate and a top side of the substrate, the pressure differential being sufficiently low to permit the substrate to remain substantially stationary during the cooling of the substrate; and
means for cooling at least a portion of the pedestal by supplying a fluid to an internal conduit inside the pedestal.
